(19) United States
(12) Patent Application Publication
(10) Pub. No.: US 2025/0253512 A1
(43) Pub. Date: Aug. 7, 2025

(54) mmWave Reconfigurable and Miniature On-Chip Filter Based on Vanadium Dioxide

(71) Applicant: Georgia Tech Research Corporation, Atlanta, GA (US)

(72) Inventor: Thomas Wiliamson, Atlanta, GA (US)

(21) Appl. No.: 19/047,390

(22) Filed: Feb. 6, 2025

Related U.S. Application Data
(60) Provisional application No. 63/550,759, filed on Feb. 7, 2024.

(51) Int. Cl. H01P 1/205; H10N 70/00; H10N 70/20

(52) U.S. Cl. CPC H01P 1/205; H10N 70/231; H10N 70/861; H10N 70/8833

(57) ABSTRACT

A reconfigurable millimeter wave filter, comprising first and second transmission line resonators and first and second shunt switches. The first and second transmission line resonators can comprise first ends electrically coupled to an input and second ends electrically coupled to a ground. The first shunt switch can be disposed within a length of the first transmission line resonator and be electrically coupled to the ground. The second shunt switch can be disposed within a length of the second transmission line resonator and be electrically coupled to the ground. The first and second shunt switches can comprise at least one phase change material, wherein application of thermal energy to the at least one phase change material of the first and second shunt switches can alter a path length of an input signal propagating along the first and second transmission lines.

### CROSS-REFERENCE TO RELATED APPLICATIONS

This application claims the benefit of U.S. Provisional Application Ser. No. 63/550,759, filed on 7 Feb. 2024, which is incorporated herein by reference in its entirety as if fully set forth below.

### FIELD OF THE DISCLOSURE

The various embodiments of the present disclosure relate generally to antennas and more particularly to mmWave reconfigurable antennas.

### BACKGROUND

Techniques for front-end filtering, and especially reconfigurable filtering, at the mmWave band (30-300 GHz) are profoundly challenging due to: large bandwidth requirements, high-loss transistor based technology, the physical limitation of acoustic wave based resonators, and the size requirements imposed by phased array systems.

The large bandwidth requirements at mmWave mean that designers should consider the dispersive nature of each component of the reconfigurable filter. Frequency dependent and non-linear properties are apparent in micro electromechanical systems (MEMS), acoustic wave resonators, varactor-diodes, and barium strontium titanate (BST) tunable capacitors. Emerging technology leveraging phase change materials (PCMs), such as vanadium dioxide (VO₂), have been shown to have ultrabroadband and highly linear performance.

Generally, the sub 30 GHz range has been dominated by acoustic wave filters. These surface acoustic wave (SAW), bulk acoustic wave (BAW), and other types of acoustic wave filters have been used in filter banks to realize reconfigurable systems. However, device physics limits the technology's feasible utility at mmWave. Thus, there are few examples of such filter technology approaching 30 GHz.

Filter banks at mmWave, using transistor-based switches, experience high insertion loss (IL). CMOS, GaN, and SiGe single-pole double-throw (SPDT) switches typically exhibit 1.8 to 3.0 dB of IL, above 30 GHz. MEMS switches have shown low loss at mmWave. However, MEMS have reliability concerns, and typically require hermetic packaging. In contrast, PCM SPDT switches with less than 1 dB of IL have been demonstrated at mmWave. Phase change material (PCM) switches have shown high reliability, and have also recently been integrated into commercial foundry processes.

Size constraints for the front-end filter, are also a significant challenge at mmWave. Arrays operating at mmWave generally have their radiating elements spaced at the free-space half-wavelength value, which is 3 mm for a 50 GHz array. Two dimensional (tiled) arrays place the front-end electronics for each antenna element within the lattice area (9 mm² at 50 GHz). To save space available for other frontend electronics, small reconfigurable on-chip filters are preferable for mmWave applications.

Reconfigurable filters have been well developed for applications below 30 GHz. Tunable capacitor designs have been demonstrated with MEMS, BST, and varactor diodes. Switched inductors, capacitors, and transmission line (TL) lengths have also been used. However, at the mmWave band, these technologies will face the linearity, reliability, and IL challenges discussed earlier. Leveraging PCMs as the mechanism for reconfiguration in the mmWave filter design could allow the designer to overcome these limitations.

### BRIEF SUMMARY

An exemplary embodiment of the present disclosure provides a reconfigurable millimeter wave filter, comprising first and second transmission line resonators and first and second shunt switches. The first transmission line resonator can comprise a first end electrically coupled to an input and a second end electrically coupled to a ground. The second transmission line resonator can comprise a first end electrically coupled to the input and a second end electrically coupled to the ground. The first shunt switch can be disposed within a length of the first transmission line resonator and be electrically coupled to the ground. The second shunt switch can be disposed within a length of the second transmission line resonator and be electrically coupled to the ground. The first and second shunt switches can comprise at least one phase change material, wherein application of thermal energy to the at least one phase change material of the first and second shunt switches can alter a path length of an input signal propagating along the first and second transmission lines.

In any of the embodiments disclosed herein, the at least one phase change material can comprise Vanadium Dioxide (VO₂).

In any of the embodiments disclosed herein, the first and second transmission lines can be parallel to each other.

In any of the embodiments disclosed herein, the filter can be in the form of a combline filter.

In any of the embodiments disclosed herein, the filter can be configured to have a first passband when the first and second shunt switches are biased and a second passband different than the first passband when the first and second shunt switches are not biased.

In any of the embodiments disclosed herein, the first switch can comprise a first microheater configured to deliver thermal energy to the at least one phase change material of the first shunt switch.

In any of the embodiments disclosed herein, the second switch can comprise a second microheater configured to deliver thermal energy to the at least one phase change material of the second shunt switch.

In any of the embodiments disclosed herein, the first microheater can be electrically isolated from the at least one phase change material of the first shunt switch.

In any of the embodiments disclosed herein, the filter can further comprise a matching circuit. The matching circuit can comprise a first capacitor electrically coupled to the first end of the first transmission line resonator and in series with the input and a second capacitor electrically coupled to the first end of the first transmission line resonator in series with ground.

In any of the embodiments disclosed herein, the first capacitor can have a capacitance equal to C_{b} and the second capacitor can have a capacitance equal to Cₐ, wherein C_{b} and Cₐ can be represented by the following equations:

$${C}_{b} = \frac{1}{ω K \sqrt{1 - {R}_{L}^{2} / {K}^{2}}}$$

$${C}_{a} = \frac{- {C}_{b}}{ω K \sqrt{1 + {( ω {C}_{b} {R}_{L} )}^{2}}}$$

wherein ω is equal to 2π multiplied by the frequency of input, R_{L} is equal to an impedance of the filter, and K is equal to a ratio of input to filter admittance.

Another embodiment of the present disclosure provides a reconfigurable millimeter wave filter, comprising a pair of transmission line resonators and at least one shunt switch. The pair of transmission line resonators can comprise first ends electrically coupled to an input and second ends electrically coupled to ground. The at least one shunt switch can be disposed along a length of the pair of transmission line resonators and electrically coupled to ground. The at least one shunt switch can comprise a phase change material wherein application of thermal energy to the at least one phase change material of the at least one shunt switch alters a path length of an input signal propagating along the pair of transmission lines resonators.

In any of the embodiments disclosed herein, the filter can exhibit a linear relationship between input and output power for input power up to 30 dBm for passbands with center frequencies in the range of 20-60 GHz.

In any of the embodiments disclosed herein, the filter can exhibit less than a 5 dB insertion loss for passbands with center frequencies in the range of 20-60 GHz.

In any of the embodiments disclosed herein, the filter can be positioned on a substrate, and the filter can occupy less than 1 square millimeter on a surface of the substrate.

These and other aspects of the present disclosure are described in the Detailed Description below and the accompanying drawings. Other aspects and features of embodiments will become apparent to those of ordinary skill in the art upon reviewing the following description of specific, exemplary embodiments in concert with the drawings. While features of the present disclosure may be discussed relative to certain embodiments and figures, all embodiments of the present disclosure can include one or more of the features discussed herein. Further, while one or more embodiments may be discussed as having certain advantageous features, one or more of such features may also be used with the various embodiments discussed herein. In similar fashion, while exemplary embodiments may be discussed below as device, system, or method embodiments, it is to be understood that such exemplary embodiments can be implemented in various devices, systems, and methods of the present disclosure.

### BRIEF DESCRIPTION OF THE DRAWINGS

The following detailed description of specific embodiments of the disclosure will be better understood when read in conjunction with the appended drawings. For the purpose of illustrating the disclosure, specific embodiments are shown in the drawings. It should be understood, however, that the disclosure is not limited to the precise arrangements and instrumentalities of the embodiments shown in the drawings.

FIG. 1 provides schematic of a mmWave reconfigurable filter, in accordance with an exemplary embodiment of the present disclosure.

FIGS. 2A-D provide (2A) an exemplary VO₂ SPST shunt switch with a tungsten (W) microheater, silicon dioxide (SiO₂) buffer for electrical isolation from the VO₂, and dc bias lines, (2B) the materials used in the fabrication of the switch, (2C) a schematic of the switch with no bias applied, and (2D) a schematic of the switch with bias applied.

FIG. 3 provides a comparison of measured performance of the exemplary SPST shunt switch with simulation.

FIG. 4 provides a schematic showing a short-circuited transmission line stub with a VO₂ shunt switch, in which the switch is used to select between different lengths of transmission line, and changing the input impedance, in accordance with exemplary embodiments of the present disclosure.

FIGS. 5A-C provide plots showing quality factors for the high-band and low-band shown in FIG. 6, vs. VO₂ gap length (5A), thickness (5B), and width (5C).

FIGS. 6A-D provide (6A) an exemplary CPW 2-band 2-pole reconfigurable filter with vanadium dioxide for mmWave applications, in which W1=50 μm, L1=232 μm, S1=40 μm, G1=45 μm, W2=90 μm, L2=370 μm, S2=10 μm, and G2=85 μm, (6B) a close up image of the bias network for the six VO₂ switches, (6C) a schematic of the electrical connection of the microheaters, and (6D) a schematic representation of the six VO₂ switches, in accordance with exemplary embodiments of the present disclosure.

FIGS. 7A-B provide schematics of (7A) a two-pole two-band combline reconfigurable filter with a/8 TLs, and (7B) a two-pole two-band interdigital filter with a/4 TLs (not to scale), in accordance with exemplary embodiments of the present disclosure.

FIGS. 8A-B provide schematics of (8A) a 3-band 2-pole reconfigurable filter, and (8B) a 3-band 3-pole reconfigurable filter, in which, as with the 2-band 2-pole version, microheaters for the VO₂ switches may be connected in series, for a single dc connection per band, in accordance with exemplary embodiments of the present disclosure.

FIG. 9 provides a schematic showing the CPW nature of the 2-band 2-pole filter in and respective capacitors, in which W1=50 μm, L1=232 μm, S1=40 μm, G1=45 μm, W2=90 μm, L2=370 μm, S2=10 μm, and G2=85 μm.

FIG. 10 provides a plot of scattering parameters for an exemplary wideband 2-band 2-pole filter generated with Ansys HFSS and Keysight ADS, in which HB=high-band, and LB=low-band.

FIG. 11 provides a plot of reflection coefficient (normalized to 600Ω) of an exemplary wide-tuning filter in its (a) low band and (b) high band states.

FIG. 12 provides a plot of reflection coefficient (normalized to 50Ω.) of a capacitive admittance inverter with a 600Ω load.

FIG. 13 provides a plot of reflection coefficient (normalized to 50Ω.) of an exemplary wide-tuning reconfigurable mmWave filter.

FIG. 14 provides a plot of scattering parameters for the wide-tuning 2-band 2-pole filter generated with Keysight ADS, in which HB=high-band and LB=low-band.

FIG. 15 provides a plot of minimum insertion loss for reconfigurable filter designs with combinations passbands and resonators, at 30 GHz.

FIG. 16 provide plots of scattering parameters showing: (16A) simulation of low-band and high-band states with high-Q and low-Q capacitors; (16B) low-band low-Q simulation (Low Q Sim), low-band high-Q simulation (High Q Sim), low-band measurement (Meas), and low-band fixed filter measurement (Fixed); and (16C) high-band low-q simulation (Low Q Sim), high-band high-q simulation (High Q Sim), high-band measurement (Meas), and high-band fixed filter measurement (Fixed).

FIG. 17 provides a plot of turn-on and turn-off of an exemplary shunt SPST VO₂ switch of the present disclosure.

FIG. 18 provides a plot of power handling of an exemplary wideband filter at 26.5 GHz, in which the input referred 1 dB compression point (iPldB) is greater than 22 dBm, which was the limit of the instrumentation used in the test setup.

### DETAILED DESCRIPTION

Although preferred exemplary embodiments of the disclosure are explained in detail, it is to be understood that other exemplary embodiments are contemplated. Accordingly, it is not intended that the disclosure is limited in its scope to the details of construction and arrangement of components set forth in the following description or illustrated in the drawings. The disclosure is capable of other exemplary embodiments and of being practiced or carried out in various ways. Also, in describing the preferred exemplary embodiments, specific terminology will be resorted to for the sake of clarity.

To facilitate an understanding of the principles and features of the present disclosure, various illustrative embodiments are explained below. The components, steps, and materials described hereinafter as making up various elements of the embodiments disclosed herein are intended to be illustrative and not restrictive. Many suitable components, steps, and materials that would perform the same or similar functions as the components, steps, and materials described herein are intended to be embraced within the scope of the disclosure. Such other components, steps, and materials not described herein can include, but are not limited to, similar components or steps that are developed after development of the embodiments disclosed herein.

As used in the specification and the appended claims, the singular forms “a,” “an” and “the” include plural referents unless the context clearly dictates otherwise.

Also, in describing the preferred exemplary embodiments, terminology will be resorted to for the sake of clarity. It is intended that each term contemplates its broadest meaning as understood by those skilled in the art and includes all technical equivalents which operate in a similar manner to accomplish a similar purpose.

Ranges can be expressed herein as from “about” or “approximately” one particular value and/or to “about” or “approximately” another particular value. When such a range is expressed, another exemplary embodiment includes from the one particular value and/or to the other particular value.

Similarly, as used herein, “substantially free” of something, or “substantially pure”, and like characterizations, can include both being “at least substantially free” of something, or “at least substantially pure”, and being “completely free” of something, or “completely pure”.

By “comprising” or “containing” or “including” is meant that at least the named compound, member, particle, or method step is present in the composition or article or method, but does not exclude the presence of other compounds, materials, particles, method steps, even if the other such compounds, material, particles, method steps have the same function as what is named.

Mention of one or more method steps does not preclude the presence of additional method steps or intervening method steps between those steps expressly identified. Similarly, it is also to be understood that the mention of one or more components in a device or system does not preclude the presence of additional components or intervening components between those components expressly identified.

The materials described as making up the various members of the invention are intended to be illustrative and not restrictive. Many suitable materials that would perform the same or a similar function as the materials described herein are intended to be embraced within the scope of the invention. Such other materials not described herein can include, but are not limited to, for example, materials that are developed after the time of the development of the invention.

Reference will now be made in detail to exemplary embodiments of the disclosed technology, examples of which are illustrated in the accompanying drawings and disclosed herein. Wherever convenient, the same references numbers will be used throughout the drawings to refer to the same or like parts.

Embodiments of the present disclosure provides a new reconfigurable filter, which leverages emerging PCM technology to create a miniature, scalable, on-chip, low-loss, high linearity, reconfigurable mmWave filter. The choice of filter topology can be essential to leveraging the maximum potential of the PCM technology. Generally speaking, on-chip inductors and capacitors at mmWave have a low quality factor (Q), so taking advantage of high Q transmission line (TL) based resonators can be preferred. Therefore, as discussed below, embodiments of the present disclosure can utilize a switched line length approach for reconfigurability. Some embodiments can also utilize a coplanar waveguide (CPW) to avoid the use of vias.

A CPW reconfigurable line length approach has been investigated previously with MEMS in an interdigital topology at frequencies approaching mmWave (K-band). A major limitation to the interdigital design, is that the switches typically must lie at alternating ends of the coupled TLs, making biasing the switches in a via free environment difficult. Therefore, as disclosed below, some embodiments disclosed herein utilize the combline architecture.

The conventional combline design terminates its TL resonators, with a short to ground, all on the same side of the filter. Thus, shunt switches may be used, and they may all be placed in a straight line. This linear placement allows for the switches to be biased in with a series dc connection, without vias. Subsequently, a single control voltage per band can be used, regardless of the number of coupled lines (poles). The biasing technique can be especially important because the dc bias lines must pass through the coupling fields of the TL resonators.

The PCM used in some embodiments of the present disclosure is VO₂ which undergoes an insulator-metal-transition (IMT) with an applied bias of heat (˜68° C.), voltage (˜3 MV/m), or a laser.

In some embodiments, the filters can utilize a thermally controlled VO₂ shunt switch. The VO₂ switch can be used to design VO₂-based mmWave tunable inductances. The modified versions of the tunable inductances can be used in a wideband (70%) 2-band 2-pole reconfigurable mmWave filter, which demonstrates the frequency stability of the line length based approach at mmWave. A wide-tuning design with narrower passbands (12%) is also disclosed. Scattering parameters, tuning speed (1-3 μs), and power handling (iPldB of >22 dBm) of some embodiments are then presented and compared with the state of the art.

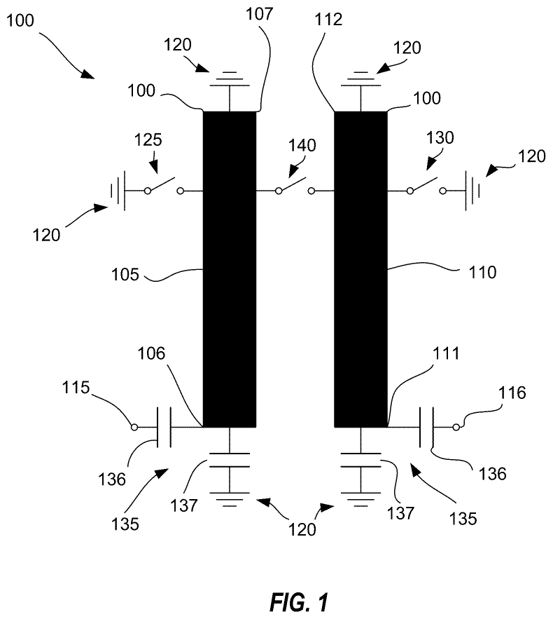

FIG. 1 provides a schematic of an exemplary embodiment of the present disclosure.

An exemplary embodiment of the present disclosure provides a reconfigurable millimeter wave filter 100. The filter 100 can comprise a first transmission line resonator 105 with capacitor 137 and second transmission line resonator 110 with capacitor 137. The transmission line resonators can be many transmission line resonators known in the art. In some embodiments, as shown in FIG. 1, the transmission line resonators 105 110 can be substantially parallel to one another. Thus, the filter 100 can be configured in a combline topology. The transmission line resonators can have first ends 106 111 electrically coupled to an input 115 and output 115, respectively. The first end 106 of the first transmission line resonator 105 can be configured to receive an input signal (e.g., from an antenna), and the first end 111 of the second transmission line 110 can be configured to deliver an output 116 (e.g., to receiver electronic circuits). The transmission line resonators 105 110 can also comprise second ends 107 112 electrically coupled to ground 120. As used herein, the term “ground” does not necessarily refer to an absolute ground, i.e., 0V, but rather to a generic low voltage connection for the filter system.

The filter 100 can further comprise first 125 and second 130 shunt switches (details described below) disposed along a length of the first 105 and second 110 transmission line resonators, respectively. Each shunt switch 125 130 can be electrically coupled to ground 120. The shunt switches can comprise at least one PCM, including, but not limited to Vanadium Dioxide (VO₂), such that application of thermal energy to the at least one PCM can result in a phase change of the PCM biasing the switch. Such a bias of the shunt switches 125 130 can alter a path length of an input signal propagating along the first and second transmission lines. The alteration of the path length of the input signal along the transmission line resonators can alter a passband of the filter. For example, when the switches 125 130 are in the unbiased state (e.g., thermal energy is not applied to the PCM of the shunt switches) the input signal can propagate an entire length of the transmission line resonators, resulting in filter having a first passband. When the shunt switches 125 130 are in the biased state (e.g., thermal energy is applied to the PCM of the shunt switches) the input signal can have a shorter path length as it propagates along the transmission line resonators resulting in a filter having a second passband different than the first passband. Accordingly, the filter is reconfigurable by the application of thermal energy to the PCM of the shunt switches 125 130.

In some embodiments, the filter 100 can further comprise a third switch 140 to electrically couple the first 105 and second 110 transmission line resonators.

In some embodiments, the shunt switches 125 130 can comprise a microheater configured to deliver thermal energy to the PCM to result in a phase change. The microheater can be many microheaters known in the art. In some embodiments, the microheater can comprise tungsten. The microheater can be electrically isolated from the PCM of the respective switch 125 130 via an electrically isolating material. The electrically isolating material can be many dielectric materials known in the art, including, but not limited to, silicon dioxide.

In some embodiments, the filter 100 can further comprise a matching circuit 135 configured to match an impedance of the input signal source and the impedance of the load which may be connected to the filter output, which is connected to the input of the filter 100, with the system impedance of the filter 100. As shown in FIG. 1, the matching circuit can comprise first capacitors 136 electrically coupled to the first ends 106 111 of the first 105 and second 110 transmission line resonators and in series with the input 115. The matching circuit 135 can further comprise second capacitors 137 electrically coupled to the first ends 106 111 of the first 105 and second 110 transmission line resonators and in series with ground 120. As discussed in detail below, the first capacitors 136 and second capacitors 137 can have capacitance values in accordance with EQs. 9 and 10 (below), respectively. For example, the first capacitors 136 can have values in accordance with EQ. 9, and the change in capacitance values of the second capacitors 137 utilized to realize the matching network can be in accordance with EQ. 10.

The process of creating the electrical design of a filter can generally follow eight steps, in a process is which is referred to as ladder synthesis by those skilled in the art. Several well establish sources can be consulted for further details. The filter synthesis process can begin with selecting the type of response and number of resonators (order). For simplicity, a 2^{nd} order (two resonator) Butterworth (maximally flat passband response) design was chosen. Using the widely published Butterworth coefficients, a canonical low-pass filter with a one radian per second cutoff frequency can be created (as a mathematical tool), with a system impedance of one ohm.

The low-pass design can begin with a capacitor connected to ground (shunt), followed by an inductor in connected in series inductance. Second, the series inductor can be transformed into a shunt capacitor using an impedance inverter. The impedance inverter, in this case, can be a purely mathematical construct. One inverter can be placed between the two circuit elements (capacitor and inductor), and the series inductor can be replaced with a shunt capacitor. In such a configuration the shunt capacitance on either side of the inverter can appear as a series inductance, to the opposite side. Thus, the circuit can maintain an equivalent performance.

Third, the filter can be transformed from lowpass to bandpass, and its center frequency can be shifted higher in frequency. This can follow the typical procedure of filter transformations found in the literature, where each shunt capacitor can be replaced with a pair inductors (L) and capacitors (C), connected in parallel to ground. Fourth, the system impedance of the filter can be scaled to 50 Ohms (or other such value, as desired) by multiplying the L and K values by 50 and dividing all C values by 50.

Fifth, the inductors in the design can be replaced with transmission line resonators (stubs), which are connected to ground (shorted) to form an equivalent inductance. Sixth, the characteristic impedance of all stubs present in the mathematical design can be equalized. The characteristic impedance of a stub can be increased so long as its parallel capacitor is also decreased by the same factor. Additionally, impedance inverters on either side of stub can be increased by the square root of the same factor. In practice, this step may not be necessary for the second order synthesis process because the two second order Butterworth coefficients can be equal. In the seventh step, the impedance inverter can be replaced with a mathematically equivalent pi (shunt-series-shunt) arrangement of shorted stubs. Also, the parallel stubs from step five are now combined with the new shunt stubs (as two parallel reactances are combined in the art), such that there are only a total of three stubs, and two capacitors remaining.

In the eighth step, the remaining three stubs can be converted into an equivalent pair of coupled lines and the physical design of the circuit can be realized. This can be done by calculating the theoretical even and odd mode impedance of the trio of stubs. Then a pair of short circuited stubs may be physically designed (given the substrate and metal thickness) for the necessary characteristic impedance and coupling such as to provide and equivalent even and odd mode impedance. The capacitors can be realized with metal contacts separated by a layer of dielectric, with one contact connected to ground and the other connected to the input/output of the filter.

### SPST VO₂ Shunt Switch

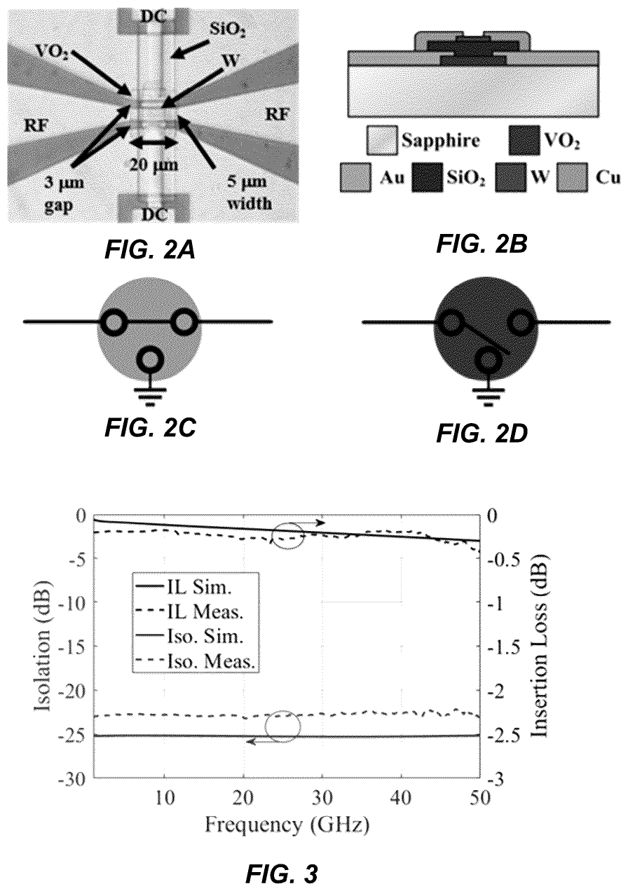

As discussed above, various embodiments of the present disclosure utilize one or more shunt switches 125 130. To that end, the shunt single pole single through (SPST) switch can be the basic building block of reconfigurable inductances, which comprise the proposed filter. An exemplary switch, illustrated in FIG. 2A, can be thermally actuated to provide a through connection or a short to ground, as in FIGS. 2C and 2D. The switch was designed and fabricated to determine the electrical properties of the VO₂ film, after processing. The coplanar waveguide (CPW) dimensions at the VO₂ can be configured to maintain a 50Ω impedance when the VO₂ is non-conductive. The 20 μm width (FIG. 2A) of the switch can be configured to provide a low-loss path to RF ground when the VO₂ is in the conductive state, with the design constraint of maintaining less than 0.5 dB of insertion loss at 50 GHz in the non-conductive state.

The switch can make a good short (low resistance) to ground (FIG. 2D) when the VO₂ is 10-15° C. above the IMT phase transition temperature (˜68° C.). At 10-15° C. below the IMT, the VO₂ can have a relatively constant high resistivity and a deviation in permittivity with temperature. However, such changes in relative permittivity are on the order of 1% between 20-60° C. above 30 GHz.

An exemplary fabrication process and materials are summarized in FIG. 2B. A 430 μm thick sapphire wafer was used as the substrate, to achieve the best possible low-loss performance with the VO₂ film. A 200 nm VO₂ film was sputtered at 650° C. in an argon and oxygen plasma and annealed in-situ. The VO₂ was then patterned with reactive ion etching (RIE). CPW traces were created via electron beam evaporation and lift-off. Plasma enhanced chemical vapor deposition (PECVD) was used to deposit silicon dioxide (SiO₂). The SiO₂ was patterned via RIE. Sputtering and lift-off was used to realize the 100 nm thick tungsten (W) microheaters. A second metal layer is deposited with electron beam evaporation and patterned with lift-off.

The simulated and measured performance of the shunt switch is summarized in FIG. 3. The VO₂ was simulated in the non-conductive state (σ=80 S/m and εᵣ=40) to determine IL, and in the conductive state (σ=3.77×10⁵ S/m and εᵣ=1) to determine isolation. The non-conductive state's measured isolation is 23 dB (vs. 25 dB simulated). FIG. 5 shows that the measured isolation is better than 20 dB over 1-50 GHz. The measured IL (0.4 dB at 50 GHz) is within ±0.1 dB of simulation.

The shunt switch's scattering parameters and its geometry were used to determine the material properties of the VO₂ film, as fabricated. The VO₂ was determined to have approximately σ=33 S/m and εᵣ=40 in the non-conductive state at 50 GHz. Likewise, in the conductive state, the properties of the deposited VO₂ were determined as ε=1.43×10⁵ S/m and εᵣ=1.

### Tunable Inductances

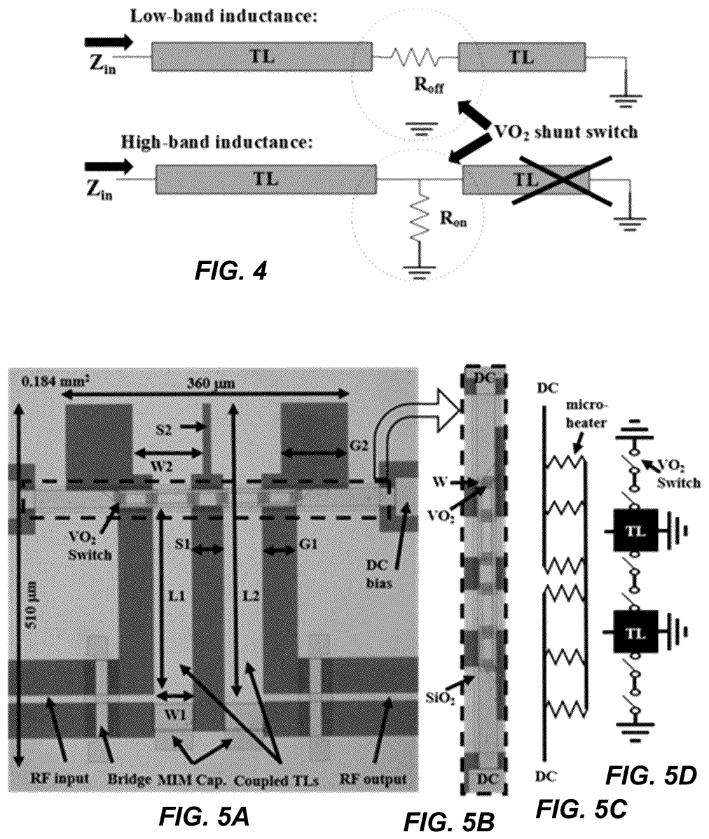

As a person of ordinary skill in the art would appreciate, a short length (stub) of transmission line (TL) terminated in a short circuit may be used to realize an inductance. The reconfigurable filters disclosed herein can have two values of inductance: one for operation at its high-band and one for its low-band (or one inductance realized at two unique resonant frequencies). A tunable inductance may be realized with the VO₂ switch from FIG. 2A and a TL, as shown in FIG. 4. The relationship between equivalent inductance (L_{eq}), transmission line dimensions, and the input impedance (Zᵢₙ) is:

$${Z}_{i n} = j ω {L}_{e q} = {jZ}_{0} tan β l . \qquad EQ . 1$$

The total amount of L_{eq} can be dictated by the characteristic impedance of the transmission line (Z₀) and the length of the line (l). A convenient design choice is for l to equal μ/8, at the center frequency of the filter, such that:

$${jZ}_{0} tan \frac{2 π}{λ} \frac{λ}{8} = j {Z}_{0} = j ω {L}_{e q} . \qquad EQ . 2$$

The choice of λ/8 for l has other convenient implications, such as simplifying the mathematical ladder synthesis process and placing a transmission zero at twice the center frequency. The λ/8 choice also determines the TL resonator quality factor in EQ. 3:

$${Q}_{high} = \frac{ω {L}_{e q}}{{R}_{total}} = \frac{{Z}_{0}}{{R}_{o n} + {R}_{α l}} . \qquad EQ . 3$$

The quality factor (Q_{high}) in EQ. 3 is a function of the characteristic impedance, the resistance to ground (Rₒₙ), and the equivalent resistance of the per-unit-length ohmic losses (Rₐᵢ) of the TL. Rₒₙ, shown in FIG. 4, is the result of the resistance of the VO₂ switch, discussed previously, which was measured to have a value of 3Ω. The per-unit-length loss of the transmission line was also measured to be 0.45 dB/mm at 37 GHz, which is 0.1 dB for a 232 μm long high-band TL, for an equivalent series resistance of approximately 1.2Ω. Thereby, Q_{high} for the tunable inductance in its high-band configuration (VO₂ shunt switch enabled), is calculated as

$${Q}_{high} = \frac{62 Ω}{3 Ω + 1.2 Ω} = 14.7 . \qquad EQ . 4$$

Q_{low} is evaluated for the low-band with the VO₂ shunt switch deactivated, so that the short to ground is replaced with a small series resistance connecting the two TL segments shown in FIG. 4. The equivalent series resistance (R_{off}) is determined as 2.3Ω, from the insertion loss (0.2 dB) of the switch at 30 GHz. The per unit length loss of the transmission line was also measured to be 0.36 dB/mm at 30 GHz, which is 0.13 dB for a 370 μm long TL, for an equivalent series resistance of approximately 1.5Ω. Likewise to EQs. 3-4, Q_{low} is calculated as:

$${Q}_{low} = \frac{{Z}_{0}}{{R}_{off} + {R}_{α l}} = \frac{62 Ω}{2.3 Ω + 1.5 Ω} = 16.3 . \qquad EQ . 5$$

The characteristic impedance in EQ. 5 is less than that in EQ. 4, in order to approximate the effective impedance of asymmetric transmission lines (differing characteristic impedances) connected in series. The reason for this asymmetry will be discussed further below. It is noteworthy that Q_{high} is approximately 0.9 of Q_{low}. Therefore, one may estimate that the resonator is 1.11× as lossy (0.5 dB of additional IL) at high-band than at low-band. This result is revisited below in the results and discussion section.

It is noteworthy that either Q_{high} or Q_{low} may be improved by modifying the switch's VO₂ geometry (length, width, or thickness), as shown in FIG. 5. The gap and width geometry are shown in FIG. 2A. As the width increases, the resistance to ground decreases. However, this change also increases the length of narrow and lossy CPW TL. Alternatively, as the gap increases, the resistance to ground increases, and the CPW line (maintaining 50Ω geometry) becomes less lossy.

### Wideband Filter Design

### Topology and Switch Integration

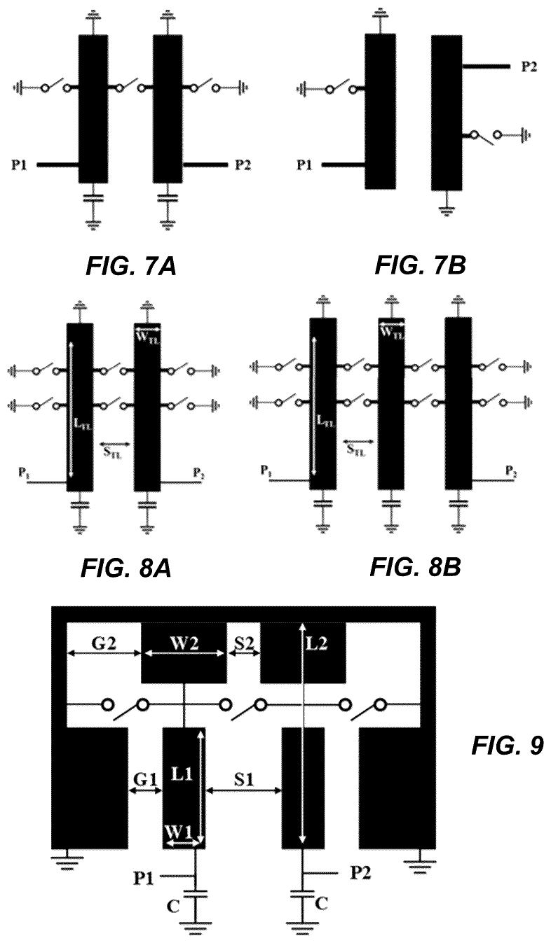

The reconfigurable mmWave filters disclosed herein (e.g., FIG. 5A and FIG. 7A) can be based on the well-known combline filter topology, which can be modified extensively to realize the final novel VO₂ based reconfigurable design. An advantage of the combline topology is its compactness, as it only requires λ/8 length lines. In contrast, the interdigital topology (FIG. 7B) requires λ/4 TLs. When used with the shunt VO₂ switch, the combline topology lends itself well to scaling to more bands (FIG. 8A) and more poles (FIG. 8B).

By modifying the switch structure (FIG. 5C), the microheaters may be biased in series and perpendicular to the TLs. The modified switches can connect to the coupled lines without reducing the line width, as shown in FIG. 5D. Increasing the number of bands can require adding an additional row of modified switches, as in FIG. 8A. None of the dc lines may be required to cross each other, so no additional layers or vias are required. To increase the order of the filter with additional poles, additional coupled lines may be added in parallel, as shown in FIG. 8B. This is because all of the VO₂ elements can lie at the same distance along the TL, in contrast to other topologies such as the interdigital (FIG. 7B).

One limitation of this topology is maximum realizable bandwidth, due to the frequency dependent equivalent inductances. Therefore, a wideband design was created to demonstrate the utility of the TL-based reconfigurable inductances disclosed herein. The design was initiated by selecting the maximally flat Butterworth polynomials for a two-pole filter to determine the inductance to capacitance ratios (UC) (e.g., inductance of transmission line resonator 105 and capacitance of the second capacitors 137, discussed above) such that the filter has a 70% 3 dB bandwidth. The process of scaling the filter's response to the desired frequency range, transforming the/C pairs into TL and capacitor pairs, incorporating electromagnetic coupling, and realizing the physical design was done by ladder synthesis.

### VO₂ Switch Integration

The filter was designed for wideband reconfiguration of its passband, a relative tuning range of 20% between the center frequencies of its passbands. The design was initially investigated for use on high resistivity silicon. However, results on sapphire showed that a lower loss VO₂ film could be realized. Therefore, the design was modified for use on sapphire, and VO₂ switches were integrated into the design as shown in FIG. 5A.

In the final design of the exemplary filter, there are a total of six VO₂ segments (FIG. 5B), rather than two shunt switches. This modification can reduce perturbations of the coupling fields caused by the metal contacts extending in from the ground plane, which can reduce the complexity of the tuning process when finalizing the filter's dimensions. However, four or even just three VO₂ segments can be sufficient, as shown in FIG. 9. Such an approach can reduce DC power requirements for the integrated microheaters, at the cost of additional design and optimization time for the electromagnetic performance.

### Integrated Microheater

The integrated tungsten microheaters were fabricated as described above. A 100Ω microheater was realized with the dimensions of 10×5 μm, with a 10 nm Ti seed layer and 90 nm W sputtered at room temperature. The microheater (without annealing) was found to have dc current handling limit of 30 mA, likely due to residual stress of the film. The current limit was not sufficient to transition the VO₂ with a 900 nm SiO₂ buffer layer. Therefore, the scattering parameter results were obtained with a heated chuck. Also, initial results have shown that the VO₂ switch with a 500 nm SiNₓ buffer layer, can be transitioned with 24 mA of current.

### MIM Capacitors

The capacitors used in the filters disclosed herein can be of the metal-insulator-metal (MIM) type. During the ladder synthesis process, the designer is free to pick the value of capacitance, as long as the inductance can be scaled proportionally, which can be limited by the realizable characteristic impedances in EQ. 2. Subsequently, a range of 10-150 fF of usable capacitor values was identified.

Additionally, the capacitors' properties (relative permittivity and dielectric loss tangent) change as a function of frequency. These quantities change more dramatically over a large change in frequency. Additionally, the changes in properties are also more pronounced at mmWave and are also true of the substrate material. Because the reconfigurable filter has both wideband instantaneous bandwidth and tuning range, minimizing the variation of capacitance with frequency is necessary for minimizing variation in filter performance as the center frequency of the passband is reconfigured.

Simulations were conducted in Ansys HFSS to investigate the frequency dependence of MIM capacitors with 900 nm thick SiO₂ insulating layers, for values of 25 and 75 fF. The smaller and larger MIM capacitors, respectively, showed a 0.6 and 8.0 fF change in capacitance between the low-band and high-band of the filter. Therefore, the value of C in FIG. 9 was selected as 25.0 fF at 34 GHz, which is 25.6 fF at 41 GHz for the original design on high resistivity silicon. When transitioning to the sapphire substrate, it was necessary to use a 118 fF capacitor at 34 GHz, which is 123 fF at 41 GHz, due in part to the change in relative permittivity from 11.9 to 9.4.

### Coupled Lines and Asymmetry

Maintaining consistent performance between the high-band and low-band of the filter requires consistent coupling between the TLs. The coupling coefficient (K) between two lines may be defined as:

$$K = \frac{{Z}_{0 , e} - {Z}_{0 , o}}{{Z}_{0 , e} + {Z}_{0 , o}} , \qquad EQ . 6$$

$$where as$$

$${Z}_{0 , e} = \frac{1}{{cC}_{a , e} \sqrt{{ε}_{eff , e}}} \qquad EQ . 7$$

$$and$$

$${Z}_{0 , o} = \frac{1}{c {C}_{a , o} \sqrt{{ε}_{eff , o )}}} . \qquad EQ . 8$$

Z_{0,e} is the even mode characteristic impedance of the lines, and Z_{0,o} is the odd mode impedance of the lines. The speed of light in vacuum is shown as c, while C_{a,e} is the even mode partial capacitance in the absence of the dielectric substrate. The odd mode partial capacitance (C_{a,o}) is defined likewise to C_{a,e}. The substrates permittivity is incorporated into the expressions for the even and odd mode effective permittivity (ε_{eff,e} and ε_{eff,o}). Hence, it may be observed that the frequency dependent permittivity will create dispersive coupling. Also, the coupling can be directly affected by the stray capacitance of the bias lines. While in the low-band state, the coupled CPW TLs can have additional capacitance due to the presence of the switches' dc bias lines. The impact of the bias lines is less pronounced for the high-band, because in that state the TLs connect to ground at the location of the bias lines. The short-circuit minimizes the voltage (electric field), which subsequently suppresses the impact of the shunt capacitance on the circuit.

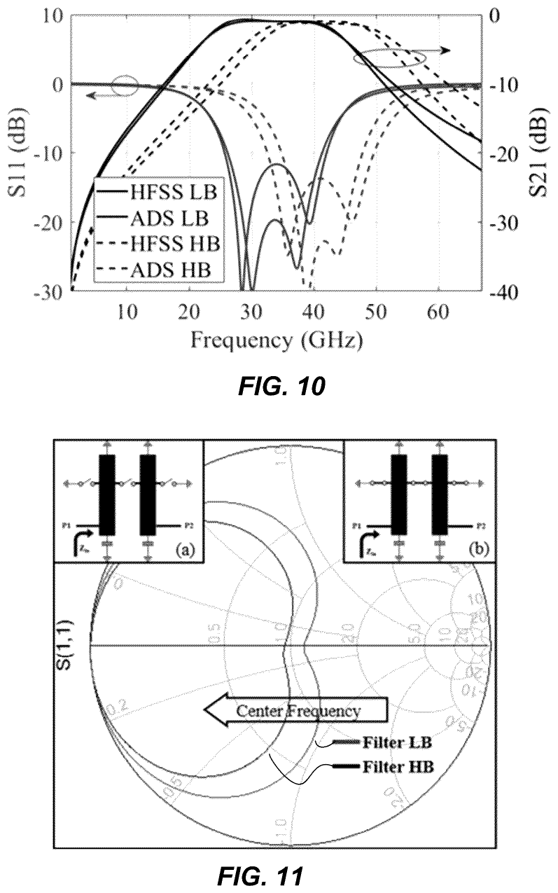

Coupled line topology was determined for the high-band portion of the design (values W1, L1, S1, and G1 of FIG. 9), with validation in Keysight ADS. Initial values for W1, L1, S1, and G1 were also obtained with Keysight ADS, and then further tuned in Ansys HFSS in the presence of the VO₂ and bias line geometry. A comparison of models is shown in FIG. 10. To compensate for the increase in capacitance from the bias line perturbations, the per-unit-length capacitance of the CPW TLs was reduced (see G2 in FIG. 9). Then W2 and S2 were tuned to readjust the lines' respective even and odd mode impedances, and restoring the canonical 12 dB/octave roll-off in insertion loss, as shown in FIG. 10. Discrepancies are due to the 2.5D vs 3D simulation methods employed.

### Wide Tuning Design

In addition to the wideband filter shown in FIG. 5A, a second wide-tuning version was also designed. The geometry of the coupled lines was modified to shift the center frequencies. Also, the passbands were narrowed (˜12%) to demonstrate narrow band filtering, compared to the wideband design's ˜70% fractional bandwidth. The wide-tuning design shifts its center frequency by 27%, compared to the wideband design which shifts by 21%.

The approach to the wide-tuning design shares the same topology and layout, but with different values for the width, spacing, length of the lines. However, the characteristic impedance of the filters in this work is frequency dependent, as shown in EQs. 7 and 8. The greater degree of frequency shift of the wide-tuning design makes change in impedance more pronounced. Also, narrowing the passbands can increase the characteristic impedance significantly. Therefore, the design can also incorporate a frequency dependent matching network.

### Dispersive Matching Network

After recalculating the geometry for the new center frequencies and bandwidths, the wide-tuning filter was simulated in Keysight ADS with the model previously developed for the wideband filter design. The narrowed bandwidth produced a characteristic impedance of approximately 600Ω, as shown in FIG. 11. The wide-tuning filter's low-band (FIG. 11A) has a 750Ω input impedance, and the high-band (FIG. 11B) has a 470Ω impedance. Note that the impedance decreases as the center frequency shifts higher.

One technique for implementing impedance matching is the capacitive admittance inverter, which is typically used for narrowband filters. The capacitive admittance inverter (FIG. 12A) mathematically transforms a purely real load impedance into the desired real impedance at the source, using a positive series capacitor (Cₐ) with a shunt negative capacitor (C_{b}). The capacitance values can be determined by EQs. 9 and 10, where K is the desired ratio of source to load admittance.

$${C}_{b} = \frac{1}{ω K \sqrt{1 - {R}_{L}^{2} / {K}^{2}}} \qquad EQ . 9$$

$${C}_{a} = \frac{- {C}_{b}}{ω K \sqrt{{1 + ω {C}_{b} {R}_{L} )}^{2}}} . \qquad EQ . 10$$

The arrangement for the positive series capacitance in EQ. 9 and the negative shunt capacitance from EQ. 10, is shown in FIG. 12A. The frequency response of the network is shown in FIG. 12, where the reflection coefficient is normalized to 50Ω. In this case the load is 600Ω and K is 12. The input impedance reduces as frequency increases. This maybe thought of as a frequency dependent ratio of source to load admittance. In other words, high admittance loads at high frequency will have a lower K, and low admittance loads at low frequency will have a higher K.

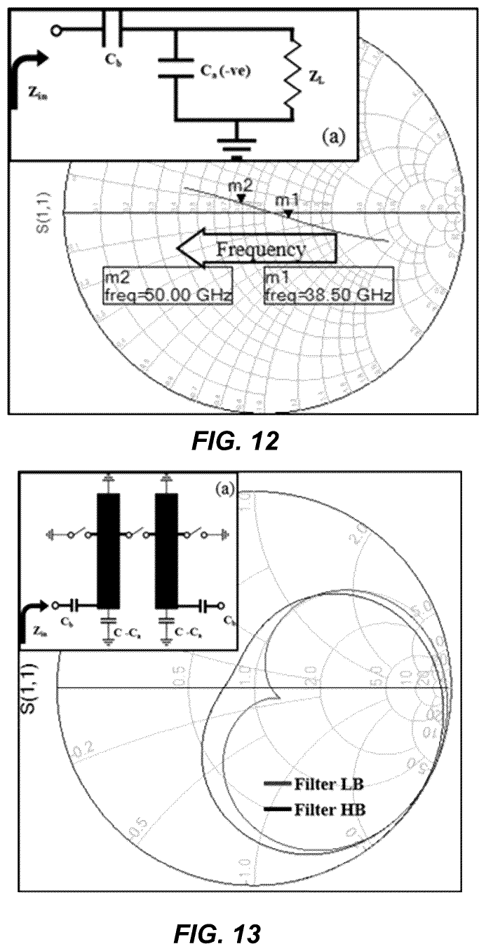

With two known input impedances, two goal values for K, two load impedances, and two center frequencies, it is possible to solve EQs. 9 and 10 iteratively for ideal values of Cₐ and C_{b} that minimize the difference from the ideal K values. Cₐ can be realized with a series MIM capacitor (e.g., first capacitors 136 in FIG. 1), and C_{b} can be realized by reducing the value of the existing shunt capacitor (e.g., second capacitors 137 in FIG. 1), as shown in FIG. 13A. FIG. 13 shows the reflection coefficient of the wide-tuning filter with its matching network, on a smith chart normalized to 50 Ω.

### Final Geometry and Simulation

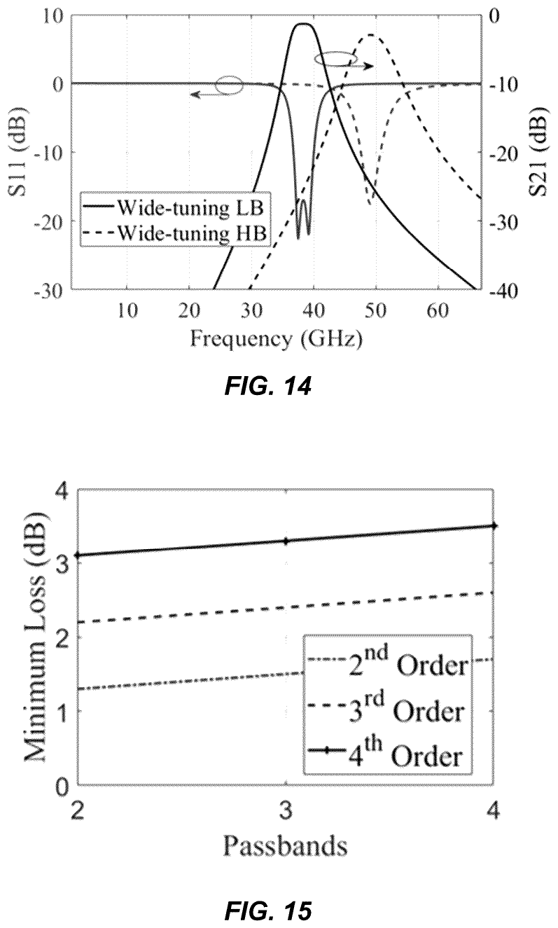

The geometry of both the exemplary wideband and wide-tuning designs are shown in Table I. The simulated performance of the wide-tuning design is shown in FIG. 14. Here, the insertion loss for the 38.5 GHz band is 1.4 dB, and the 49 GHz band has 3.0 dB of insertion loss. The is a 27% shift in frequency between the passbands. The return loss is better than 15 dB for both bands. The fractional 3 dB bandwidths are 12.1% (4.7 GHz) and 12.3% (6.0 GHz) respectively. The narrow bandwidth and wide tuning range complements the wideband filter performance (FIG. 10), in terms of exploring the design potential of the VO₂ based reconfigurable mmWave filter.

TABLE I

| Design | W1 | W2 | S1 | S2 | L1 | L2 | G1 | G2 |
|---|---|---|---|---|---|---|---|---|
| Wideband | 50 | 90 | 40 | 10 | 232 | 370 | 45 | 85 |
| Wide-tuning | 40 | 70 | 370 | 315 | 245 | 395 | 50 | 50 |

The wide-tuning design's roll-off of IL is as expected for a canonical second order filter, when bandwidth and center frequency are properly accounted for. The presence of the dispersive matching network causes negligible distortion of the filter's out-of-band attenuation, to within 1 dB of expected values (up to 15 GHz from the edge of the passband). Thus, the transmission coefficient is well understood and predictable for bandwidths of 12-70%, with center frequencies up to 50 GHz.

The wide-tuning and the wideband filters have similar simulated values of IL for their low-bands (1.3 and 1.4 respectively). The IL varies between the high-band and low-band, due to the quality of the match (FIG. 13). Also, for both versions of the filter, the maximum IL depends on the maximum frequency, the capacitors (Section VI), and the use of a matching network as needed. The minimum IL, shown in FIG. 14, depends on the number of resonators (order) and number of passbands. Simulation results for the wideband (FIG. 10) and wide-tuning (FIG. 14) filters show that the inter-resonator coupling loss is approximately 0.6 dB at 30-40 GHz, with BWs of 12-70% (calculated by subtracting VO2 switch and TL per-unit-length losses, from discussion of tunable inductance above). FIG. 15 shows that the number of resonators has the greatest impact on IL. The designer may estimate the in-band insertion loss and the out-of-band attenuation of higher order versions of the filter, filters with more passbands, and combinations thereof.

### Measurements and Discussion

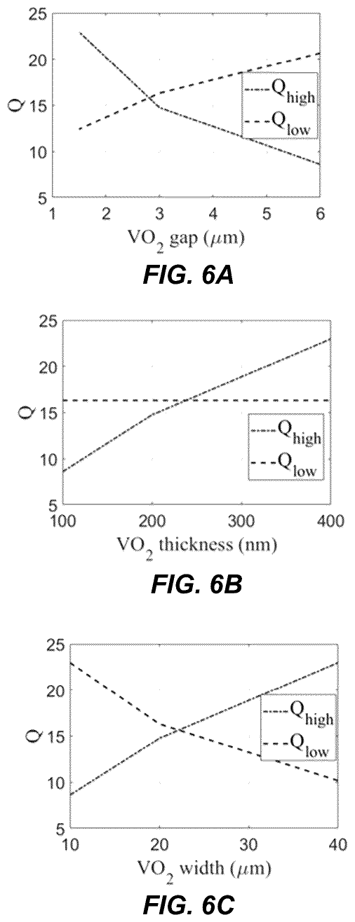

A wideband reconfigurable filter was fabricated with the process discussed above. FIG. 6A shows the core dimensions of the device are 510×360 μm, which is a 0.184 mm² area. For reference, the free space half wavelength distance at 50 GHz is 3 mm, which is an inter-element lattice area of 9 mm². Thus, the filter occupies just 2% of the of the space available in a 50 GHz tiled array.

### Scattering Parameters

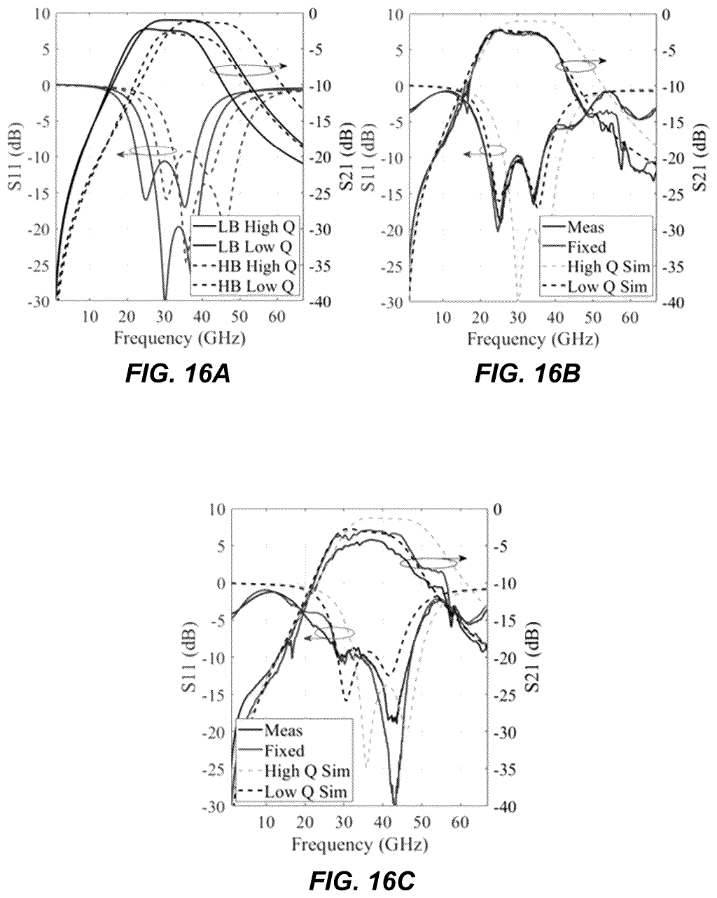

FIG. 16A shows the simulated scattering parameters of the wideband filter in the low-band and high-band states, with low-Q and high-Q capacitors. The high-Q capacitors are simulated as incorporating high quality pure SiO₂. The low-Q capacitors have the same geometry as the high-Q capacitors, and include the properties of amorphous silicon, as resulted from the fabrication process. The wideband filter was also simulated with the same initial VO₂ properties as the switch. With the as fabricated low-Q capacitors, the simulated passband IL are 2.5 and 3.2 dB, respectively. Additionally, the high-Q simulations show an IL of 1.3 and 1.8 dB, which agrees with the quality factor analysis above that predicted a difference of 0.5 dB for the bands. Therefore, the insertion loss performance of the reconfigurable filter may be further improved by 1.2-1.4 dB with improvements in fabrication and processing.

FIG. 16B shows low-band simulations and measurement for the wideband reconfigurable filter. The low-band low-q simulations (Low Q Sim) included the low-Q capacitors discussed previously. The low-band high-Q simulation (High Q Sim) includes the high-Q ideal capacitors with all else equal. The measured reconfigurable filter with VO₂ (Meas) includes low-Q capacitors, as fabricated. Additionally, FIG. 16B includes measurements of a fixed filter (Fixed), which has the same geometry and low-Q capacitors, but no VO₂. The 30.1 GHz centered passband has a measured IL of 2.7 dB for the reconfigurable filter with VO₂ (Meas), which agrees with the low-Q simulation to within 0.2 dB. The fixed filter (no VO₂) has a measured and 2.9 dB, which agrees with the IL of the reconfigurable filter to within 0.2 dB also. The measured return loss for both bands of the filter is shown to be 10 dB or better. The measured 3 dB bandwidth is 22 GHz.

FIG. 16C shows high-band simulations and measurement for the wideband reconfigurable filter. The high-band low-q simulations (Low Q Sim) included the low-Q capacitors discussed previously. The high-band high-Q simulation (High Q Sim) includes the high-Q ideal capacitors with all else equal. The measured reconfigurable filter with VO₂ (Meas) includes low-Q capacitors, as fabricated. Additionally, FIG. 16C includes measurements of a fixed filter (Fixed), which has the same geometry and low-Q capacitors, but no VO₂. The 36.5 GHz centered passband has a measured IL of 4.4 dB for the reconfigurable filter with VO₂ (Meas), which agrees with the low-Q simulation to within 1.2 dB. The fixed filter (no VO₂) has a measured and 3.1 dB. The additional IL for the high-band of the reconfigurable filter was determined to be caused by VO₂ film thickness variation introduced during the fabrication process. The measured return loss for both bands of the filter is shown to be 10 dB or better. The measured 3 dB bandwidth is 22.3 GHz.

The high-band state exhibits 1.7 dB more IL than the low-band state. The Q factor analysis above explains 0.5 dB of the relative difference in IL, and the remaining 1.2 dB corresponds with VO₂ film thickness variation of 50 nm. Improvements of IL may be realized by improving the Q of the tunable inductances, discussed above, with higher resolution lithography and other fabrication techniques. Furthermore, FIG. 16 shows that improving the Q of the capacitors via high fidelity dielectric deposition (at a foundry or similarly sophisticated fabrication environment), can improve IL performance by approximately 1.3 dB.

### Switching Speed

The reliability of VO₂ based switches has been previously documented as showing no degradation of performance after one hundred million cycles. The exemplary reconfigurable filter's switching speed was assessed by evaluation of its constituent VO₂ shunt switch. A function generator was used to apply a control waveform to turn on and off the switch. The voltage across the switch is then monitored with an oscilloscope connected to the output. The VO₂ was thermally biased with a heated chuck to 52° C., which is 16° C. below the transition temperature. A 40 kHz square wave, with a 500 mVₚₚ (peak-to-peak) amplitude and a 500 mV offset (750 mV maximum applied voltage) excites the switch.

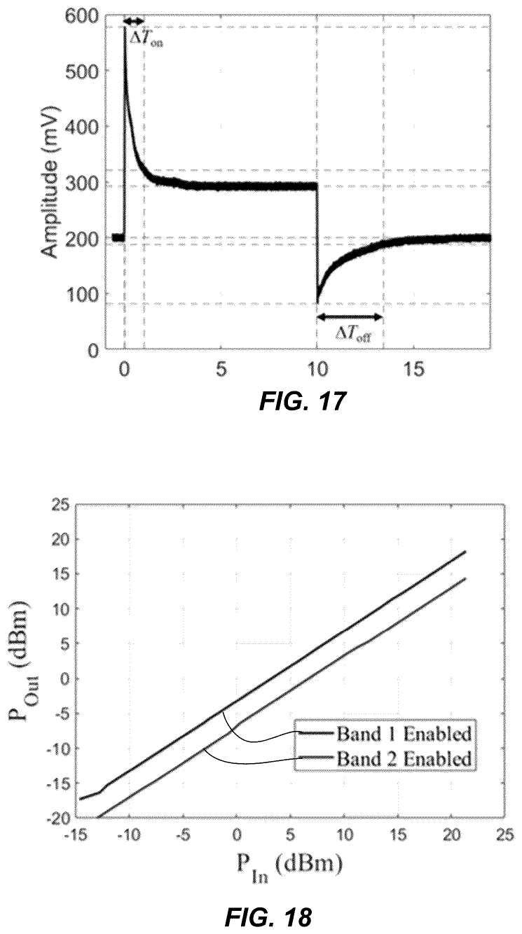

The waveform sampled in FIG. 17 shows the transition of the VO₂'s resistance, from high-to-low and low-to-high values. The measured voltage drops exponentially as the VO₂ becomes a small resistance to ground. This small resistance draws the maximum (limited) current of the function generator (100 mA), and at steady state, it is shown that the total resistance to ground is approximately 3Ω. The 3Ω value agrees with the measured values determined with S-parameter measurements earlier (at 95° C.). The transition to the conductive state occurs in approximately 1.01 μs. Once the voltage waveform of the function generator swings to 250 mV, the current limit also reduces proportionally (at 10 μs in FIG. 17). Here, a smaller current through the VO₂ creates a smaller measured voltage. The voltage rises as the resistance of the switch increases, and reaches its steady state in 3.04 μs.

The average of the turn-on and the turn-off times for the shunt switch is 2.03 μs. Also, the shift in the measured passbands is 6.4 GHz. Therefore, the filter's tuning speed was assessed to be 3.16 GHz/μs.

### Power Handling

The power handling of the reconfigurable filter was measured at 26.5 GHz. The thermal chuck was used to transition the VO₂ for both power handling and scattering parameter measurements. A signal generator (Keysight E8257D) is used to produce the 26.5 GHz tone, which is amplified by a high frequency HPA (QuinStar QPW-18283330-HB04) with a maximum output of 31 dBm. Two isolators (Ditom model D312640) were used to suppress backward traveling reflected power, and protect the test equipment. A coupler (Krytar model 102040013) and an attenuator (realized with a long length of cable) were used to connect a power sensor (Keysight E4413A) and measure the output of the amplifier. Likewise, a second power sensor, protected by an in-line attenuator, measured the power output.

The power of the 26.5 GHz tone applied to the filter was gradually increased from −14 dBm to its maximum, in 1 dB increments. The filter performed linearly up to the maximum input power (limited by HPA and losses from interconnects) of 22 dBm, as shown in FIG. 18. The curves are offset by 4 dB of output power, because the high-band state of the filter has higher insertion loss at 26.5 GHz than the low-band state. Subsequently, the 1 dB compression point of the filter was assessed to be greater than 22 dBm.

Comparable mmWave Tunable Filter Technology

Table II shows this work with comparable mmWave on-chip reconfigurable filter technologies, which operate at or above 30 GHz, including MEMS (Ref. 1, 2, and 3) ferroelectrics (Ref. 4 and 5) varactor-diodes in 130 nm SiGe (Ref. 7), N-path filters in 45 nm CMOS (Ref. 6 and 8), a sampling technique based time approximate filter in 28 nm CMOS (Ref. 10), and a photonic integrated circuit (PIC) filter with CMOS circuitry (Ref. 9). The measured performance of the wideband filter (TW¹) is shown with the simulated performance of wide-tuning filter (TW²).

| | | Range¹ | | | IL | iP1dB | Area |
|---|---|---|---|---|---|---|---|
| Ref. | Tech. | (GHz) | Range² | FBW | (dB) | (dBm) | (mm²) |
| 1 | MEMS | 60-78.5 | 31% | 13-25% | 6.7 | NR | 1.781 × 10¹ |
| 2 | MEMS | 56-75 | 34% | 5-12% | 6.2-9.9 | NR | 1.82 × 10⁰ |
| 3 | MEMS | 27.4-29 | 5.8% | 6.2-7.3% | 1.9-4.0 | NR | 2.3 × 10⁰ |
| 4 | BST | 48.1-52.1 | 8.3% | 8.7-9.5% | 4.9-7.6 | NR | 3.0 × 10⁰ |
| 5 | HZO | 60.5-69.7 | 15.2% | 29-33% | 3.0-3.3 | NR | 6.2 × 10⁻² |
| 6 | 45 nm | 6-31 | 416% | 17-3.9% | 4.5-6.6 | −7.4 to −2 | 2.25 × 10⁰ |
| | CMOS | | | | | | |
| 7 | 130 nm | 44.5-49 | 10.1% | 9.0-8.2% | 8.4-12.5 | NR | 2.3 × 10⁰ |
| | SiGe | | | | | | |
| 8 | 45 nm | 6-31 | 416% | 6.1-4.0% | 5.7-7.3 | −5.7 to −2 | 1.95 × 10⁰ |
| | CMOS | | | | | | |
| 9 | SOI | 30-45 | 50% | 7-17% | −25 | −6.4 | 9.49 × 10⁰ |
| | PIC | | | | | | |
| 10 | 28 nm | 31-37 | 19% | 1.4-2.1% | −6 | −6 | 1.5 × 10⁰ |
| | CMOS | | | | | | |
| TW¹ | VO₂ | 30.1-36.5 | 21.2% | 73-61% | 2.7-4.4 | >22 | 1.84 × 10⁻¹ |
| TW² | VO₂ | 38.5-49.0 | 27.2% | 12.1-12.3% | 1.4-3.0 | >22 | 5.1 × 10⁻¹ |

NR = not reported,
FBW = fractional bandwidth,
TW¹ = this work: wideband design measured,
TW² = this work: wide-tuning design simulated,
IL = insertion loss,
iP1dB = input referred 1 dB compression point,
Range¹ = range of center frequencies,
Range² = |Range¹|/f_{c, low}
1: K. Y. Chan, R. Ramer, R. R. Mansour, and Y. J. Guo, “60 GHz to E-Band Switchable Bandpass Filter,” IEEE Microw. Wireless Compon. Lett., vol. 24, no. 8, pp. 545-547, August 2014, doi: 10.1109/LMWC.2014.2321294.
2: P. Rynkiewicz et al., “Tunable dual-mode ring filter based on BiCMOS embedded MEMS in V-band,” in Proc. Asia-Pacific Microw. Conf., November 2017, pp. 124-127, doi: 10.1109/APMC.2017.8251393.
3: S. Dey and S. K. Koul, “Reliable, Compact, and Tunable MEMS Bandpass Filter Using Arrays of Series and Shunt Bridges for 28-GHz 5G Applications,” IEEE Trans. Microw. Theory Techn., vol. 69, no. 1, pp. 75-88, January 2021, doi: 10.1109/TMTT.2020.3034182.
4: H. Jiang, B. Lacroix, K. Choi, Y. Wang, A. T. Hunt, and J. Papapolymerou, “Ka- and U-Band Tunable Bandpass Filters Using Ferroelectric Capacitors,” IEEE Trans. Microw. Theory Techn., vol. 59, no. 12, pp. 3068-3075, December 2011, doi: 10.1109/TMTT.2011.2170088.
5: S. Abdulazhanov, Q. H. Le, D. K. Huynh, D. Wang, G. Gerlach, and T. Kämpfe, “A Tunable mmWave Band-Pass Filter Based on Ferroelectric Hafnium Zirconium Oxide Varactors,” in Proc. IEEE MTT-S Int. Microw. Workshop Adv. Mater. Processes RF THz Appl. (IMWS-AMP), July 2019, pp. 46-48, doi: 10.1109/IMWS-AMP.2019.8880098.
6: S. Hari, C. J. Ellington, and B. A. Floyd, “A Reflection-Mode N-Path Filter Tunable From 6 to 31 GHz,” IEEE J. Solid-State Circuits, vol. 58, no. 7, pp. 1973-1986, July 2023, doi: 10.1109/JSSC.2023.3235976.
7: A. Moradinia, C. D. Cheon, C. T. Coen, N. E. Lourenco, A. S. Cardoso, and J. D. Cressler, “A 42.5-51.0 GHz SiGe BiCMOS Integrated Tunable Bandpass Filter and Attenuator,” in Proc. IEEE BiCMOS Compound Semicond. Integr. Circuits Technol. Symp. (BCICTS), October 2022, pp. 183-186, doi: 10.1109/BCICTS53451.2022.10051694.
8: C. J. Ellington, S. Hari, and B. A. Floyd, “Improved Out-of-Band Rejection in Reflection-Mode N-Path Filters Using Tunable Transmission Zeros,” IEEE Trans. Microw. Theory Techn., pp. 1-12, 2024, doi: 10.1109/TMTT.2024.3395060.
9: R. Rady, Y.-L. Luo, C. Madsen, S. Palermo and K. Entesari, “An mm-Wave CMOS/Si-Photonics Reconfigurable Hybrid-Integrated Heterodyning Software-Defined Radio Receiver,” IEEE Trans. Microw. Theory Techn., vol. 72, no. 5, pp. 2824-2839, May 2024, doi: 10.1109/TMTT.2024.3371914.
10: C. Yang, S. Su and M. S.-W. Chen, “Millimeter-Wave Receiver With Non-Uniform Time-Approximation Filter,” IEEE J. Solid-State Circuits, vol. 58, no. 5, pp. 1201-1211, May 2023, doi: 10.1109/JSSC.2023.3243044.

The range of reconfigurable center frequencies is shown in Table II as Range¹. The relative tuning range (Range²) is the Range¹ bandwidth divided by the filter's lowest center frequency. The tuning range of the wideband VO₂ filter is 21.2%, and the simulation results for the wide-tuning design show a tuning range of 27.2%. The VO₂ filter's tuning range is surpassed by one MEMS filter (34%) with comparatively high IL (6.2-9.9 dB). The photonic integrated circuit filter has 50% value for Range², while occupying relatively large area (9.49 mm²). The designs with active components offer the greatest tuning range (up to 416%). Additionally, the maximum possible tuning range for alternative designs of the reconfigurable combline filter is dictated by cut-off frequency of the CPW TLs for the high frequency. The low frequency limit of the tuning range is a function of the space available for the λ/8 TLs.

The instantaneous fractional bandwidth (FBW in Table II) is normalized to passband center frequency. Generally, there is a variation in FBW between the different passbands of the reconfigurable filters, so a minimum and maximum FBW is shown in Table II. The FBW of the wideband reconfigurable filter (TW¹) demonstrates that the topology disclosed herein can be leveraged for ultrawide bandwidths, while utilizing a frequency dependent inductance. The simulation results for the wide-tuning design show that narrower passbands may be implemented (12%). Furthermore, the proposed filter may be designed for an application specific combination of passbands and poles, as discussed previously with regards to wide tuning design.

The IL shown in Table II, is the insertion loss at the center frequency, and this value is shown as negative for circuits with gain. Considering that the HZO (Ref. 5) filter's IL results are form simulation only, the VO₂ filter (TW¹) has lower IL (2.7-4.4 dB) than the SiGe varactor design (8.4-12.5 dB), ferroelectric filters (4.9-7.6 dB), and all other MEMS filters (4.9-9.9 dB), except one (1.9-4.0 dB). Additionally, the VO₂ filter's IL may be further improved by 1.3 dB with enhancements to the fabrication process to realize high-Q capacitors (Section VI-A). Moreover, the VO₂ based filter has none of the packaging or reliability concerns which are common for MEMS devices.

The size of the filter is 0.184 mm². Considering that the HZO filter's results are from simulation only, the VO₂ filter (TW1) is the smallest measured filter in Table II. Size, considered with bandwidth and tuning range, make the filter well suited for broadband mmWave phased array systems. combination of low-loss, high-power handling, and reliability are advantageous in a frontend filter.

The measured iPldB point of the VO₂ filter is above 22 dBm. The iPldB point is 24 dB greater than the highest reported value in Table II. Such a combination of low loss and high power handling are advantageous in a frontend filter.

### Findings

As disclosed herein, the present disclosure provides a novel reconfigurable on-chip mmWave filter. Two generic designs (wideband and wide-tuning) were developed and simulated. A 2-pole 2-band wideband filter was fabricated and measured in the lab. The measured parameters were compared with the state of the art.

Power handling measurements have shown that the input referred 1 dB compression (iPldB) point is above 22 dBm, at 26.5 GHz. The reconfigurable on-chip filter provides this high power handling in a compact footprint of 0.184 mm². This combination of power handling and footprint is the current state of the art, as shown in Table II.

The state of the art performance of the reconfigurable filter makes it especially advantageous for mmWave arrays which have limited space available for their frontend electronics. Additionally, the filter is well suited to a wide range of broadband reconfigurable filtering applications at mmWave. To the best of the authors' knowledge, this work is the first on-chip mmWave reconfigurable filter based on a phase change material, e.g., VO₂.

It is to be understood that the embodiments and claims disclosed herein are not limited in their application to the details of construction and arrangement of the components set forth in the description and illustrated in the drawings. Rather, the description and the drawings provide examples of the embodiments envisioned. The embodiments and claims disclosed herein are further capable of other embodiments and of being practiced and carried out in various ways. Also, it is to be understood that the phraseology and terminology employed herein are for the purposes of description and should not be regarded as limiting the claims.

Accordingly, those skilled in the art will appreciate that the conception upon which the application and claims are based may be readily utilized as a basis for the design of other structures, methods, and systems for carrying out the several purposes of the embodiments and claims presented in this application. It is important, therefore, that the claims be regarded as including such equivalent constructions.

Furthermore, the purpose of the foregoing Abstract is to enable the United States Patent and Trademark Office and the public generally, and especially including the practitioners in the art who are not familiar with patent and legal terms or phraseology, to determine quickly from a cursory inspection the nature and essence of the technical disclosure of the application. The Abstract is neither intended to define the claims of the application, nor is it intended to be limiting to the scope of the claims in any way.

What is claimed is:

1. A reconfigurable millimeter wave filter, comprising:
a first transmission line resonator comprising a first end electrically coupled to an input and a second end electrically coupled to a ground;
a second transmission line resonator comprising a first end electrically coupled to an output and a second end electrically coupled to the ground;
a first shunt switch disposed within a length of the first transmission line resonator the first shunt switch electrically coupled to the ground; and
a second shunt switch disposed within a length of the second transmission line resonator the second shunt switch electrically coupled to the ground,
wherein the first and second shunt switches comprise at least one phase change material, wherein application of thermal energy to the at least one phase change material of the first and second shunt switches alters a path length of an input signal propagating along the first and second transmission lines.

2. The filter of claim 1, wherein the at least one phase change material comprises Vanadium Dioxide (VO₂).

3. The filter of claim 1, wherein the first and second transmission lines are parallel to each other.

4. The filter of claim 1, wherein the filter is in the form of a combline filter.

5. The filter of claim 1, wherein the filter is configured to have a first passband when the first and second shunt switches are biased and a second passband different than the first passband when the first and second shunt switches are not biased.

6. The filter of claim 1, wherein the first switch comprises a first microheater configured to deliver thermal energy to the at least one phase change material of the first shunt switch.

7. The filter of claim 7, wherein the second switch comprises a second microheater configured to deliver thermal energy to the at least one phase change material of the second shunt switch.

8. The filter of claim 7, wherein the first microheater is electrically isolated from the at least one phase change material of the first shunt switch.

9. The filter of claim 1, further comprising a matching circuit comprising:
a first capacitor electrically coupled to the first end of the first transmission line resonator and in series with the input;
a second capacitor electrically coupled to the first end of the second transmission line resonator and in series with the output;
a third capacitor electrically coupled to the first end of the first transmission line resonator in series with ground; and
a fourth capacitor electrically coupled to the first end of the second transmission line resonator in series with ground.

10. The filter of claim 9, wherein the first capacitor and second capacitor have a capacitance equal to C_{b} and the third capacitor and fourth capacitor having a capacitance based at least in part on Cₐ, wherein C_{b} and Cₐ are represented by the following equations:
$${C}_{b} = \frac{1}{ω K \sqrt{1 - {R}_{L}^{2} / {K}^{2}}}$$
$${C}_{a} = \frac{- {C}_{b}}{ω K \sqrt{1 + {( ω {C}_{b} {R}_{L} )}^{2}}}$$
wherein ω is equal to 2π multiplied by the frequency of input, R_{L} is equal to an impedance of the filter, and K is equal to a ratio of input to filter admittance.

11. A reconfigurable millimeter wave filter, comprising:
a pair of transmission line resonators comprising first ends electrically coupled to an input and output and second ends electrically coupled to ground; and
at least one shunt switch disposed along a length of the pair of transmission line resonators, the at least one shunt switch electrically coupled to ground, the at least one shunt switch comprising a phase change material wherein application of thermal energy to the at least one phase change material of the at least one shunt switch alters a path length of an input signal propagating along the pair of transmission lines resonators.

12. The filter of claim 11, wherein the at least one phase change material comprises Vanadium Dioxide (VO₂).

13. The filter of claim 11, wherein pair of transmission line resonators are parallel to each other.

14. The filter of claim 11, wherein the filter is in the form of a combline filter.

15. The filter of claim 11, wherein the filter is configured to have a first passband when the at least one shunt switch is biased and a second passband different then the first passband when the at least one shunt switch is not biased.

16. The filter of claim 11, wherein each of the at least one switches comprises a microheater configured to deliver thermal energy to the at least one phase change material of the respective at least one shunt switch.

17. The filter of claim 17, wherein the microheater is electrically isolated from the at least one phase change material of the respective at least one shunt switch.

18. The filter of claim 11, wherein the filter exhibits a linear relationship between input and output power for input power up to 30 dBm for passbands with center frequencies in the range of 20-60 GHz.

19. The filter of claim 11, wherein the filter exhibits less than a 5 dB insertion loss for passbands with center frequencies in the range of 20-60 GHz.

20. The filter of claim 11, wherein the filter is positioned on a substrate, and wherein the filter occupies less than 1 square millimeter on a surface of the substrate.
